(19) United States
(12) Patent Application Publication
(10) Pub. No.: US 2025/0151252 A1
(43) Pub. Date: May 8, 2025

(54) COMPONENT MOUNTING MACHINE AND COMPONENT MOUNTING METHOD

(71) Applicant: FUJI CORPORATION, Chiryu (JP)

(72) Inventor: Masayoshi MORIYAMA, Gifu-shi (JP)

(73) Assignee: FUJI CORPORATION, Chiryu (JP)

(21) Appl. No.: 18/835,894

(22) PCT Filed: Mar. 25, 2022
(86) PCT No.: PCT/JP2022/014367

§ 371 Date: Aug. 5, 2024

(51) Int. Cl. H05K 13/08; H05K 13/02; H05K 13/04

(52) U.S. Cl. CPC H05K 13/086; H05K 13/021; H05K 13/0404; H05K 13/0419

(57) ABSTRACT

A component mounting machine includes a mounting control section to execute a mounting process based on a control program in which an execution order of a PP cycle including a collection operation of components and a mounting operation of mounting the components on a board is set, a supply control section to, when the collectable quantity of components in a bulk feeder to supply multiple components in a bulk state is less than a reference value, cause the bulk feeder to execute a supply operation of the components in parallel to a mounting cycle, and an order adjustment section to, when a required time for a mounting operation scheduled to be executed in parallel with the next supply operation scheduled based on the current collectable quantity is shorter than a required time for the supply operation, adjust an execution order of the PP cycle including the mounting operation.

### TECHNICAL FIELD

The present disclosure relates to a component mounting machine and a component mounting method.

### BACKGROUND ART

A component mounting machine executes a mounting process of mounting components supplied by a feeder or the like on a board. As disclosed in Patent Literature 1, there is a type of feeder described above in which components are supplied in a bulk state in which the components are scattered in a supply region where the components are collectable by a suction nozzle. In a mounting process, a component mounting machine executes image processing of recognizing a supply state of components by such a bulk feeder, and controls a pickup operation of picking up a component using a suction nozzle based on the result of the image processing.

### PATENT LITERATURE

Patent Literature 1: JP-A-2011-114084

### BRIEF SUMMARY

### Technical Problem

In the mounting process, when the collectable quantity of components supplied by the bulk feeder is less than the required quantity for a collection operation, a part of the scheduled mounting operations cannot be executed, or a supply operation of the bulk feeder may need to wait, potentially leading to a decrease in production efficiency. As described above, when executing the mounting process using the bulk feeder, it is desirable to cause the supply operation to be executed at an appropriate execution timing in consideration of the fact that the collectable quantity of components supplied by the bulk feeder is indefinite.

An object of the present description is to provide a component mounting machine and a component mounting method capable of preventing a decrease in production efficiency in a mounting process using a bulk feeder.

### Solution to Problem

The present description discloses a first component mounting machine including: a mounting control section configured to execute a mounting process based on a control program in which an execution order of a PP cycle including a collection operation of components and a mounting operation of mounting the components on a board is set; a supply control section configured to, when the collectable quantity of components in a bulk feeder configured to supply multiple components in a bulk state is less than a reference value, cause the bulk feeder to execute a supply operation of the components in parallel to a mounting cycle in which the mounting operation is repeated multiple times; and an order adjustment section configured to, when a required time for the mounting cycle scheduled to be executed in parallel with the next supply operation scheduled based on the current collectable quantity is shorter than a required time for the supply operation, adjust an execution order of the PP cycle including the mounting cycle.

The present description discloses a second component mounting machine including: a component supply device including a bulk feeder configured to supply multiple components in a bulk state and a tape feeder configured to feed and move a carrier tape accommodating the same type of components as the bulk feeder to supply the components; a mounting control section configured to execute a mounting process based on a control program in which an execution order of a PP cycle including a collection operation of the components and a mounting operation of mounting the components on a board is set; and a supply control section configured to, when the collectable quantity of components in the bulk feeder is less than a reference value, cause the bulk feeder to execute a supply operation of the components in parallel with the PP cycle, in which the mounting control section is configured to, when executing the collection operation, switch a collection target to the components supplied by the tape feeder when waiting time for waiting for completion of the supply operation of the components by the bulk feeder occurs.

The present description discloses a component mounting method including: a mounting control step of executing a mounting process based on a control program in which an execution order of a PP cycle including a collection operation of components and a mounting operation of mounting the components on a board is set; a supply control step of causing, when the collectable quantity of components in a bulk feeder configured to supply multiple components in a bulk state is less than a reference value, the bulk feeder to execute a supply operation of the components in parallel to a mounting cycle in which the mounting operation is repeated multiple times; and an order adjustment step of adjusting, when a required time for the mounting cycle scheduled to be executed in parallel with the next supply operation scheduled based on the current collectable quantity is shorter than a required time for the supply operation, an execution order of the PP cycle including the mounting cycle.

### Advantageous Effects

With such a configuration of the first component mounting machine and the component mounting method, the execution order of multiple PP cycles is appropriately adjusted based on the required quantity and the collectable quantity. Accordingly, it is possible to prevent occurrences such as insufficient collectable quantity or waiting time for the completion of the supply operation of the bulk feeder, during the execution of the PP cycles. As a result, a decrease in production efficiency can be prevented.

Further, with the configuration of the second component mounting machine, when the supply operation of the bulk feeder is required, since the collection target is switched to the components supplied by a tape feeder capable of supplying the same type of components as the bulk feeder, the occurrence of waiting time for the completion of the supply operation of the bulk feeder can be prevented. As a result, a decrease in production efficiency can be prevented.

### BRIEF DESCRIPTION OF DRAWINGS

FIG. 1 is a plan view schematically showing a component mounting machine according to a first embodiment.

FIG. 2 is a plan view showing a supply region of components in a bulk feeder.

FIG. 3 is a block diagram showing the component mounting machine.

FIG. 4 is a diagram showing image data obtained by imaging the supply region.

FIG. 5 is a diagram showing a result of recognition processing of a supply state for the image data in FIG. 4.

FIG. 6 is a table showing a control program and analysis results for each PP cycle.

FIG. 7 is a flowchart showing a mounting process by the component mounting machine.

FIG. 8 is a flowchart showing a supply management process of the components by the component mounting machine.

FIG. 9 is a timing chart showing a relationship between the PP cycle scheduled to be executed and the adjusted PP cycle.

FIG. 10 is a flowchart showing a PP cycle adjustment process by the component mounting machine.

FIG. 11 is a diagram of a cycle generation process by the component mounting machine.

FIG. 12 is a flowchart showing a supply management process of the components by a component mounting machine according to a second embodiment.

### DESCRIPTION OF EMBODIMENTS

### 1. First Embodiment

A component mounting machine and a component mounting method for executing a mounting process of components using bulk feeder 30 will be described with reference to the drawings. Bulk feeder 30 is provided on, for example, component mounting machine 10 that mounts components on board 91, and supplies the components in a bulk state (loose state in which postures of components are irregular).

### 1-1. Configuration of Component Mounting Machine 10

Component mounting machine 10 configures a production line for producing board products together with multiple types of board work machines including, for example, another component mounting machine 10. The board work machines configuring the production line described above can include a printer, an inspection device, a reflow oven, and the like.

### 1-1-1: Board Conveyance Device

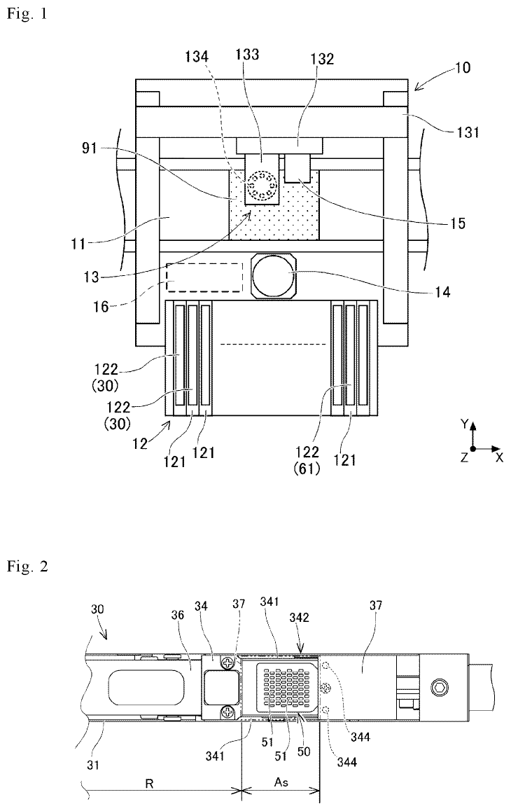

As shown in FIG. 1, component mounting machine 10 includes board conveyance device 11. Board conveyance device 11 subsequently conveys board 91 in a conveyance direction and positions board 91 at a predetermined position within the machine.

### 1-1-2. Component Supply Device 12

Component mounting machine 10 includes component supply device 12. Component supply device 12 supplies components to be mounted on board 91. Component supply device 12 includes feeders 122 which are provided individually in multiple slots 121. For example, a tape feeder that feeds and moves a carrier tape accommodating a large number of components to supply the components to be collectable is applied to feeder 122. In addition, bulk feeder 30 which supplies components accommodated in a bulk state to be collectable is applied to feeder 122. Details of bulk feeder 30 will be described below.

In addition, feeder 122 is loaded with components to enable feeder 122 to be able to supply the required types of components in accordance with the mounting process scheduled to be executed and is provided in slots 121. When the component shortage occurs during the execution of the mounting process, the mounting process temporarily stops, and the production efficiency decreases. Therefore, in the mounting process, the practice of providing spare feeder 61 capable of supplying the same type of components to other slots 121 may be adopted.

### 1-1-3. Component Transfer Device 13

Component mounting machine 10 includes component transfer device 13. Component transfer device 13 transfers components supplied by component supply device 12 into a predetermined mounting position on board 91. Component transfer device 13 includes head driving device 131, moving table 132, mounting head 133, and suction nozzles 134. Head driving device 131 moves moving table 132 in a horizontal direction (X-direction and Y-direction) by a linear motion mechanism. Mounting head 133 is detachably fixed to moving table 132 by a clamp member, not shown, and is provided to be movable in the horizontal direction in the mounting machine.

Mounting head 133 supports multiple suction nozzles 134 to be rotated, and lifted and lowered. Suction nozzle 134 is a holding member that collects and holds a component supplied by feeder 122. Suction nozzle 134 picks up a component supplied by feeder 122 using supplied negative pressure air. As a holding member to be attached to mounting head 133, a chuck or the like that holds the component by gripping the component can be adopted.

### 1-1-4. Part Camera 14 and Board Camera 15

Component mounting machine 10 includes part camera 14 and board camera 15. Part camera 14 and board camera 15 are digital imaging devices having imaging elements, such as CMOS. Part camera 14 and board camera 15 execute imaging based on control signals and transmit image data acquired by the imaging. Part camera 14 is configured to image a component held by suction nozzle 134 from below. Board camera 15 is provided on moving table 132 to be movable in the horizontal direction integrally with mounting head 133. Board camera 15 is configured to image board 91 from above.

In addition to using a surface of board 91 as an imaging target, board camera 15 can use various devices or the like as the imaging target as long as various devices are within a movable range of moving table 132. For example, in the present embodiment, as shown in FIG. 2, board camera 15 can image supply region As to which bulk feeder 30 supplies components or fiducial marks 344 provided on an upper part of bulk feeder 30 within the camera's field of view. As described above, board camera 15 can be used commonly to image different imaging targets to acquire the image data used for various pieces of image processing.

### 1-1-5. Control Device 20

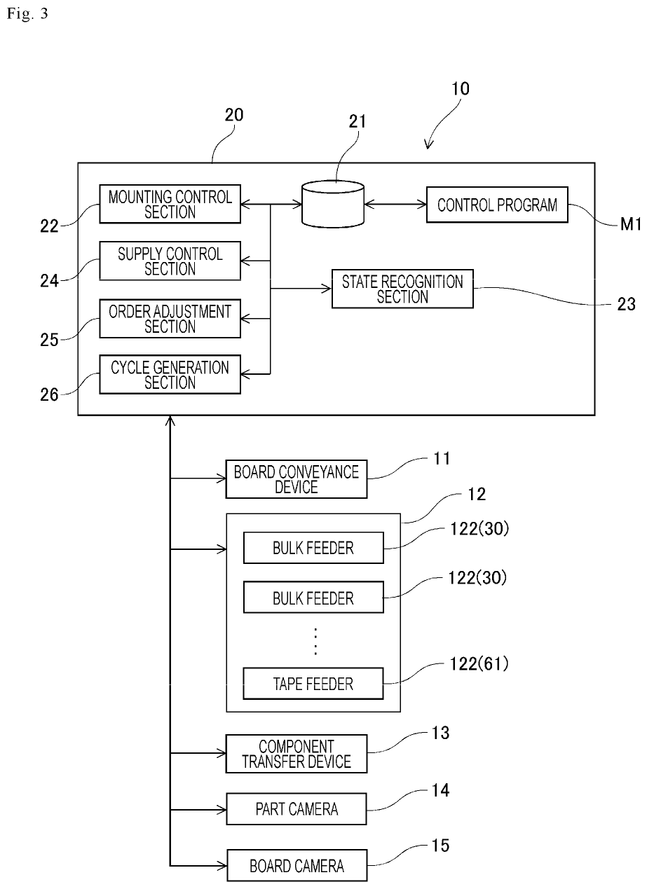

As shown in FIG. 1, component mounting machine 10 includes control device 20. Control device 20 is mainly made up of CPU, various types of memory, and a control circuit. Control device 20 includes storage section 21 as shown in FIG. 3. Storage section 21 includes an optical drive device such as a hard disk device or a flash memory. Various data such as control program M1 used for controlling a mounting process and the like are stored in storage section 21 of control device 20.

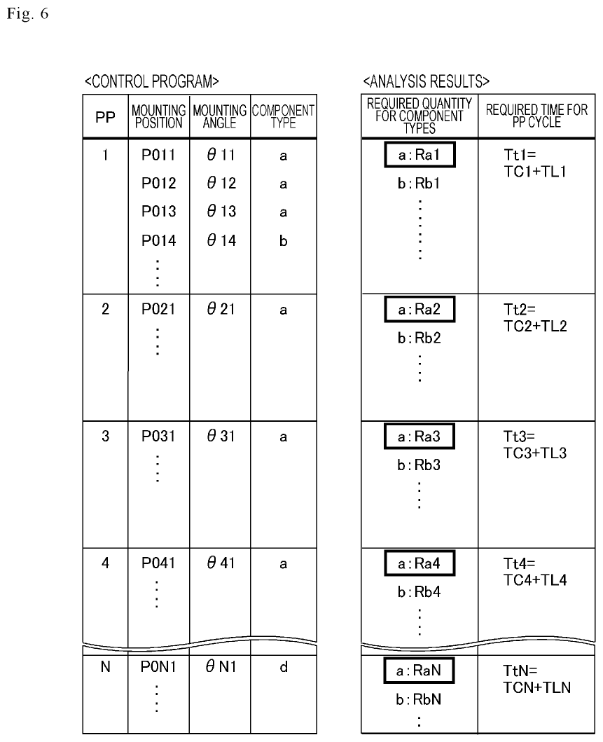

As shown in FIG. 6, control program M1 indicates the mounting position, mounting angle, and component type of the components to be mounted on board 91 in the mounting process in the scheduled mounting order. Here, the mounting process includes a process of repeating a PP cycle (pick-and-place cycle) including a collection cycle and a mounting cycle, multiple times. The “collection cycle” described above is a process of repeating a collection operation by suction nozzle 134 to collect the components supplied by component supply device 12, multiple times.

The “mounting cycle” described above is a process of repeating a mounting operation to mount the collected components at predetermined mounting positions and at predetermined mounting angles on board 91, multiple times. As described above, in control program M1, the execution order (PP1, PP2, and so on) of the PP cycle including multiple collection operations and mounting operations grouped in consideration of the number of suction nozzles 134 supported by mounting head 133, the moving distance of mounting head 133, and the like are set in advance.

Control device 20 includes mounting control section 22. Mounting control section 22 executes the mounting process based on control program M1 in which the execution order of the PP cycle is set. Mounting control section 22 executes recognition processing of recognizing a holding state of each of the components held by the multiple holding members (suction nozzles 134). Specifically speaking, mounting control section 22 executes image processing on image data acquired by imaging of part camera 14 and recognizes the position and angle of each component with respect to a reference position of mounting head 133. In addition to part camera 14, mounting control section 22 may execute the image processing on the image data acquired by imaging the component by a head camera unit or the like provided integrally with mounting head 133 from side, below, or above.

In the mounting process, mounting control section 22 controls the operation of mounting head 133 based on information output from various sensors, the result of image processing, control program M1, or the like. As a result, the positions and the angles of multiple suction nozzles 134 supported by mounting head 133 are controlled. As a result, the component held by suction nozzle 134 is mounted at a predetermined mounting position instructed by control program M1 at a predetermined mounting angle.

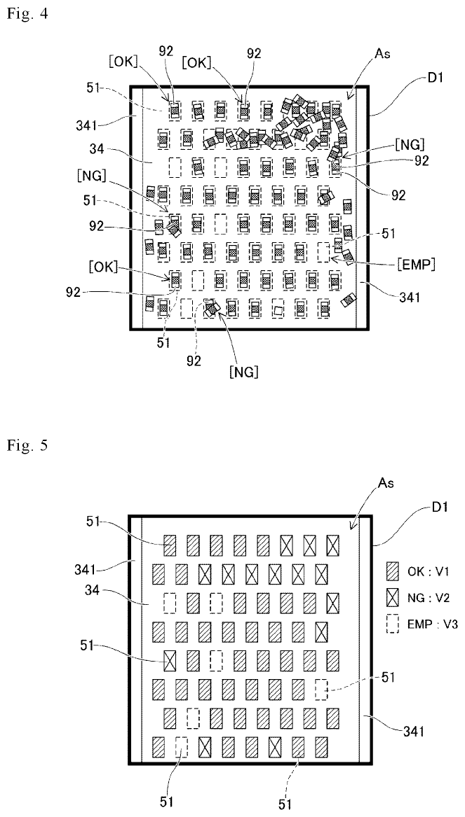

Control device 20 includes state recognition section 23. State recognition section 23 recognizes the supply state of multiple components in supply region As of bulk feeder 30 based on image data D1 (refer to FIG. 4) acquired by the imaging of the camera (in the present embodiment, board camera 15). Recognition processing of the supply state includes a processing step of recognizing whether there are collectable components in supply region As and a processing step of, when there are collectable components, recognizing positions and angles of those components. Moreover, mounting control section 22 controls an operation of mounting head 133 in the collection operation based on a result of the recognition processing of the supply state. Details of the recognition processing by state recognition section 23 will be described later.

Control device 20 includes supply control section 24. Supply control section 24 controls the component supply by component supply device 12. When bulk feeder 30 is provided in component supply device 12, supply control section 24 causes the supply operation by bulk feeder 30 to be executed at an appropriate execution timing during the execution of the mounting process. Details of the control for bulk feeder 30 by supply control section 24 will be described later.

Control device 20 includes order adjustment section 25. Here, in the PP cycle, which is repeated multiple times in the mounting process, the execution order is set in advance by control program M1 as described above. However, in the actual mounting process, there are cases where a part of the mounting operations in the PP cycle are not completed successfully due to errors in the component collection operation or the presence of defective components. In such a case, order adjustment section 52 adjusts the execution order of the PP cycle.

For example, when mounting operations that were not completed successfully occur, order adjustment section 25 moves the set of the mounting operations relating to the mounting operation to the middle or the end of the scheduled PP cycle. Thereby, mounting control section 22 attempts the mounting operations again as recovery processing. In addition, in the present embodiment, in addition to the circumstances described above, order adjustment section 25 adjusts the execution order of the predetermined PP cycle in accordance with the supply operation of bulk feeder 30 and the progress of the mounting process. Details of the PP cycle adjustment process by order adjustment section 25 will be described later.

Control device 20 includes cycle generation section 26. When the execution order of a part of the PP cycle is changed by order adjustment section 25, cycle generation section 26 groups predetermined mounting operations under predetermined conditions to generate new PP cycles. Accordingly, for example, multiple mounting operations targeted for the recovery processing are grouped into one PP cycle. Details of the PP cycle generation process by cycle generation section 26 will be described later.

### 1-2. Configuration of Bulk Feeder 30

Bulk feeder 30 is provided on component mounting machine 10 and functions as a part of component supply device 12. Bulk feeder 30 supplies components which are accommodated in a bulk state in which the components are not aligned as in a carrier tape. Therefore, since bulk feeder 30 does not use the carrier tape unlike the tape feeder, there is an advantage in that loading of the carrier tape, collection of the used tape, or the like can be omitted.

For example, there is bulk feeder 30 of a type that supplies components in irregular postures to planar supply region As. However, when the components are so close to one another to contact, the components are accumulated (a state of being overlapped in a vertical direction), or the components are in a horizontally standing posture in which the width direction of the component is directed in the vertical direction in supply region As, component mounting machine 10 cannot regard these components as a collection target. Then, in order to increase a ratio of collectable components, there is bulk feeder 30 of a type that supplies components to supply region As in an aligned state. In the present embodiment, bulk feeder 30 of the type in which the components are aligned will be described as an example.

When bulk feeder 30 is set in slots 121 of component supply device 12, bulk feeder 30 is supplied with power via a connector, and is in a state that bulk feeder 30 can communicate with control device 20. Bulk feeder 30 includes feeder main body 31 formed in a flat box shape. A component case for accommodating multiple components in a bulk state is detachably attached to feeder main body 31. Bulk feeder 30 includes trajectory member 34 that is provided to be capable of vibrating with respect to feeder main body 31. Trajectory member 34 is formed with conveyance path R through which multiple components are conveyed, and supply region As that communicates with conveyance path R and is open upwards such that the multiple components are collectable.

Trajectory member 34 is formed to extend in a front-rear direction (left-right direction in FIG. 2) of feeder main body 31. Pair of side walls 341 protruding upwards is formed on both edges of trajectory member 34 in a width direction (a vertical direction in FIG. 2). Pair of side walls 341 surround the peripheral edge of conveyance path R together with tip end portion 342 of trajectory member 34 to prevent leakage of the components conveyed on conveyance path R. Pair of left and right circular fiducial marks 344 each indicating a reference position of supply region As is affixed to an upper surface of tip end portion 342.

In the present embodiment, alignment member 50 is exchangeably attached to trajectory member 34. Alignment member 50 has multiple cavities 51 that individually accommodate multiple components. Specifically, multiple cavities 51 are arranged in a zigzag shape in which rows adjacent to each other are staggered in the conveyance direction in supply region As. For example, alignment member 50 has 64 cavities 51 in total in which 8 cavities are regularly arranged in the conveyance direction and 8 cavities are regularly arranged in the width direction of conveyance path R. Each of multiple cavities 51 is open upwards to accommodate the component in a posture in which a thickness direction of the component is in the vertical direction. Multiple cavities 51 may be arranged in a matrix.

The opening of cavity 51 is set to a dimension slightly larger than an outer shape of the component as viewed from above. The depth of cavity 51 is set in accordance with the type (shape, mass, or the like) of the component. One trajectory member 34 selected from various types of trajectory members 34 based on the type of component, the required quantity of cavities 51, and the functionality is attached to trajectory member 34.

Here, “supply region As” of trajectory member 34 is a region to which components are supplied in a bulk state, and is a region from which the component is collectable by suction nozzle 134 supported by mounting head 133. In addition, “conveyance path R” of trajectory member 34 is a path of the component along which the component circulated from the component case side to trajectory member 34 is conveyed to supply region As. Cover 36 that covers an upper portion of conveyance path R is fixed to trajectory member 34.

Bulk feeder 30 includes shutter 37 provided on an upper part of trajectory member 34 and capable of closing the opening of supply region As. By opening or closing shutter 37, bulk feeder 30 can prevent the component from protruding and foreign matters from entering supply region As. Shutter 37 is switched between an open state, a closed state, and an intermediate state by an opening/closing operation. The closed state of shutter 37 is a state in which shutter 37 contacts trajectory member 34 and the opening of supply region As is completely closed. At this time, as indicated by dashed lines in FIG. 2, shutter 37 is positioned behind feeder main body 31 with respect to pair of fiducial marks 344 of trajectory member 34, and pair of fiducial marks 344 can be visually recognized and imaged as viewed from above.

The open state of shutter 37 is a state in which the opening of supply region As is not closed and a principal range of supply region As (range in which multiple cavities 51 are provided in the present embodiment) is exposed. At this time, suction nozzle 134 can execute the component collection operation on any of cavities 51. The intermediate state of shutter 37 is a state between the closed state and the open state in which shutter 37 is separated from trajectory member 34 by at least the amplitude of trajectory member 34 vibrated by the excitation, and restricts the protruding of the component from the opening of supply region As. The opening/closing operation of shutter 37 is executed by a driving device (not shown), and shutter 37 is placed in the closed state, the open state, and the intermediate state in accordance with a driving state of the driving device.

Bulk feeder 30 includes an excitation device provided in feeder main body 31. The excitation device applies vibration to trajectory member 34 so that multiple components are conveyed along conveyance path R. When the excitation device applies vibration to trajectory member 34, trajectory member 34 performs an elliptical motion in the side view. As a result, a forward and upward external force or a rearward and upward external force is applied to multiple components at conveyance path R in accordance with a rotational direction of the elliptical motion of trajectory member 34. As a result, the multiple components are conveyed to the front side or conveyed to the rear side of trajectory member 34. Bulk feeder 30 can vary the conveyance speed of components to be conveyed, the degree of dispersion of components, the conveyance direction, and the like by controlling the frequency and amplitude of the vibration applied to trajectory member 34, and the rotation direction of the elliptical motion caused by the vibration.

The bulk feeder configured as described above receives an instruction to supply components during the mounting process by component mounting machine 10, for example, during a period from the completion of the current collection operation to the start of the next collection operation, and executes the supply operation of the components. The supply operation of the components is an operation of conveying components to accommodate the components in multiple cavities 51. Specifically, the conveyance operation includes a feed operation in which the components positioned at the front end portion of conveyance path R move forward to the front end of supply region As, followed by a return operation in which the components move backward again to the front end portion of conveyance path R.

When there is sufficient time before the start of the next collection operation, in the conveyance operation, the feed operation and the return operation may be repeatedly executed to cause the multiple components to reciprocate in the front-rear direction multiple times in supply region As. That is, in the supply operation of the components in bulk feeder 30, one pattern selected from multiple patterns can be selectively executed in consideration of the circumstances such as the allowable time and the securement of the collectable quantity.

### 1-3. Details of State Recognition Section 23

As described above, state recognition section 23 recognizes the supply state of multiple components 92 in supply region As of bulk feeder 30 based on image data D1 (refer to FIG. 4) acquired by the imaging of board camera 15. More specifically, state recognition section 23 first executes the recognition processing of the supply state based on image data D1 acquired by imaging supply region As in a state in which bulk feeder 30 conveys multiple components 92 to supply region As by the vibration.

FIG. 4 shows an example of image data D1. As described above, in supply region As, a large quantity of components 92 in the bulk state are present, and for example, the component accommodated in cavity 51 in a normal posture, the component outside cavity 51, the components that contact each other or deposited on each other, and the component in the horizontal posture can be present. In the present embodiment, state recognition section 23 first calculates a state for each of multiple cavities 51.

Thus, multiple cavities 51 are classified into accommodating cavities (“OK” in FIG. 5) in which components 92 are accommodated to be collectable, NG cavities (“NG” in FIG. 5) in which components 92 are present in the periphery but cannot be collectable, and empty cavities (“EMP” in FIG. 5) in which components 92 are not present in the periphery. FIG. 5 shows the accommodating cavities with diagonal lines, the NG cavities with an X mark formed by diagonal lines, and the empty cavities with only the outline shown in dashed lines. As shown in FIG. 5, state recognition section 23 calculates the numbers (V1, V2, V3) of the states (OK, NG, EMP) of multiple cavities 51.

Then, state recognition section 23 recognizes the current supply state based on the numbers (V1, V2, V3) described above. The supply state may include the ratio of number V1 of accommodating cavities to the total number of cavities 51, the address of accommodating cavities as the position of collectable components 92 (the unique value assigned to each of multiple cavities 51), and the posture of component 92 in the accommodating cavity (the angle of collectable component 92). The ratio of number V1 of accommodating cavities is used, for example, for switching various patterns in the supply operation. In the following description, the “number V1 of accommodating cavities” is also referred to as “collectable quantity V1” of components 92.

### 1-4. Details of Supply Control Section 24

As described above, when bulk feeder 30 is provided in component supply device 12, supply control section 24 causes the supply operation by bulk feeder 30 to be executed at an appropriate execution timing. Various aspects may be adopted for the execution timing of the supply operation. For example, different execution timings are set when priority is given to reducing the number of executions of the supply operation and when priority is given to reducing the number of executions of the PP cycle including the recovery processing.

In the present embodiment, supply control section 24 performs control prioritizing reducing the number of executions of the supply operation. Specifically, first, supply control section 24 determines whether collectable quantity V1 of components 92 in bulk feeder 30 is less than reference value Vc. Specifically, supply control section 24 acquires collectable quantity V1 included in the supply state recognized by state recognition section 23, and updates collectable quantity V1 by subtracting the required quantity in the PP cycle (for example, required quantity Ra for component type a) from collectable quantity V1 each time the PP cycle is executed. When updated collectable quantity V1 becomes less than reference value Vc, supply control section 24 instructs bulk feeder 30 to execute the supply operation.

Reference value Vc can be set as appropriate. In the present embodiment, reference value Vc is set to 1. That is, supply control section 24 instructs bulk feeder 30 to execute the supply operation at the point in time when collectable quantity V1 becomes 0. In such a setting, when the required quantity of components 92 cannot be collected from bulk feeder 30 during execution of a certain PP cycle, mounting control section 22 omits a part of the PP cycle and transitioning to the mounting operation for collected components 92. Mounting control section 22 executes the omitted part of the PP cycle (collection operation and mounting operation) at a predetermined timing similarly to the recovery processing.

When supply control section 24 instructs bulk feeder 30 to execute the supply operation as described above, supply control section 24 sends the instruction after the collection operation from bulk feeder 30 is completed and suction nozzle 134 is raised sufficiently. Thus, the supply operation by bulk feeder 30 is executed in parallel with the mounting cycle of the PP cycle.

### 1-5. Mounting Process by Component Mounting Machine 10

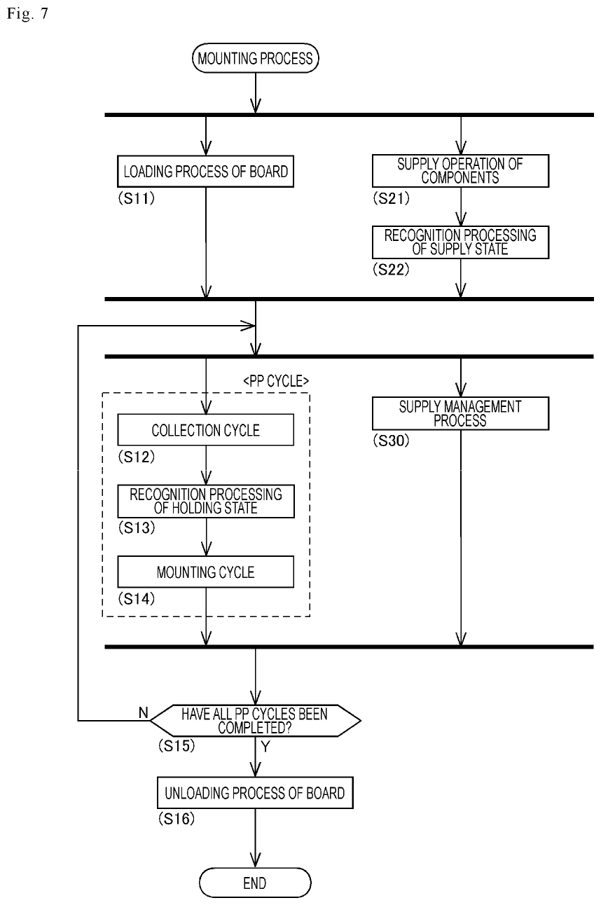

Referring to FIG. 7, a mounting process by component mounting machine 10 will be described. Here, component supply device 12 is provided with a tape feeder and bulk feeder 30 which are multiple feeders 122. After bulk feeder 30 is set in slots 121, control device 20 executes calibration processing and recognizes the positions of multiple cavities 51 in the machine.

In the calibration processing described above, control device 20 first moves board camera 15 above pair of fiducial marks 344 of bulk feeder 30, and acquires image data by imaging of board camera 15. Moreover, control device 20 recognizes the position of bulk feeder 30 in the machine based on the positions of pair of fiducial marks 344 included in the image data by image processing and the positions of board camera 15 when the image is captured. Control device 20 can acquire the coordinate values of individual cavities 51 based on a result of the calibration processing and arrangement information of cavities 51.

In the mounting process, first, as shown in FIG. 7, board conveyance device 11 of component mounting machine 10 executes a loading process of board 91 (S11). As a result, board 91 is loaded into the machine and positioned at a predetermined position in the machine. Supply control section 24 executes the supply operation by bulk feeder 30 after S11 or in parallel with S11 (S21). By executing the supply operation, multiple components 92 are accommodated in at least a part of multiple cavities 51 of bulk feeder 30. After the supply operation by bulk feeder 30 is completed, state recognition section 23 executes recognition processing of the supply state of components 92 (S22). As a result, current collectable quantity V1 and the position of collectable components 92 (the address of the accommodating cavities) are acquired as the supply state.

Next, control device 20 executes the PP cycle. In the PP cycle, mounting control section 22 executes the collection cycle in which the collection operation of collecting components 92 is repeated using multiple suction nozzles 134 (S12). In this case, mounting control section 22 causes the operation of mounting head 133 in the collection operation to subsequently position mounting head 133 in accordance with the positions of collectable components 92. In this case, mounting control section 22 appropriately switches the coordinate value that is the center of cavity 51 or the coordinate value of the reference position of component 92 as the position of collectable component 92, and positions suction nozzle 134.

Subsequently, control device 20 executes the recognition processing of the holding state of components 92 held by multiple suction nozzles 134 (S13). Specifically, control device 20 moves mounting head 133 above part camera 14 and sends an imaging command to part camera 14. Control device 20 executes the image processing on the image data acquired by the imaging of part camera 14 to recognize the posture (position and angle) of component 92 held by each of multiple suction nozzles 134. The result of the recognition processing of the holding state (S13) is recorded in storage section 21 as an operation result indicating whether the collection error occurs in the collection operation.

Thereafter, control device 20 executes the mounting cycle in which the mounting operation of mounting the components is repeated using multiple suction nozzles 134 (S14). In the mounting operation of mounting cycle (S14), control device 20 causes the operation of mounting head 133 to mount each of components 92 at the mounting position designated by control program M1. Further, control device 20 controls the operation of mounting head 133 such that suction nozzle 134 is positioned and angled with respect to the mounting position based on the result of the recognition processing (S13).

Supply control section 24 executes the supply management process in parallel with the PP cycle as described above. The supply management process includes the setting of the execution timing of the supply operation of components 92 by bulk feeder 30, the instruction of the supply operation, the recognition processing of the supply state, and the like. For example, when the supply operation of components 92 is executed, the supply operation by bulk feeder 30 is executed in a period from the completion of the collection cycle (S12) of the current PP cycle to the start of the next collection cycle (S12) of the PP cycle.

Control device 20 determines whether all the PP cycles have been completed based on control program M1 (S15). When all the PP cycles have not been completed (S15: No), the PP cycle (S12 to S14) is executed. When all the PP cycles have been completed (S15: Yes), control device 20 executes an unloading process of board 91 (S16). In the unloading process of board 91, board conveyance device 11 unclamps positioned board 91 and unloads board 91 outside component mounting machine 10.

### 1-6. Supply Management Process by Component Mounting Machine 10

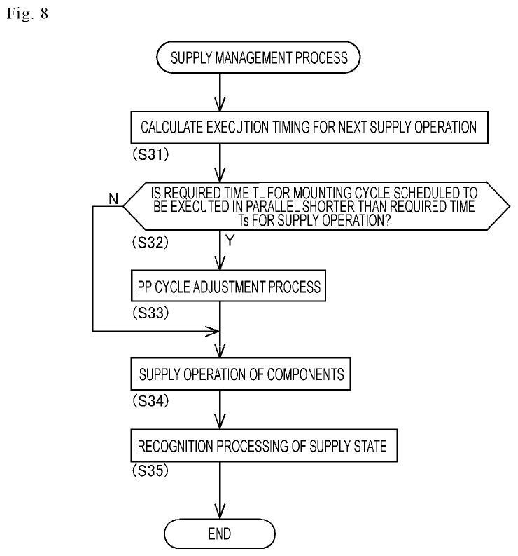

The supply management process by component mounting machine 10 will be described with reference to FIG. 8. The supply management process of components 92 is executed before the execution of the PP cycle or in parallel with a part of the steps during the execution of the mounting process. First, control device 20 calculates the execution timing for the next supply operation (S31). Control device 20 integrates the required quantity of components 92 for each PP cycle to be executed in the execution order of the PP cycle, and calculates the time when the sum of the integrated value and reference value Vc exceeds current collectable quantity V1 as the execution timing of the next supply operation.

For example, as shown in FIG. 6, control device 20 analyzes control program M1 in advance, and acquires the required quantity (Ra1, Rb1, . . . ) for component types in multiple PP cycles (PP1, PP2, . . . ). FIG. 6 shows required quantity Ra for component type (a) as required quantity Ra1, Ra2, . . . , RaN in each PP cycle (PP1, PP2, . . . , PPN). Then, when the component type (a) is supplied by bulk feeder 30, control device 20 integrates required quantity Ra during execution of the first PP cycle (PP1), for example, and calculates the time when the sum of the integrated value (Ra1+Ra2+ . . . ) and reference value Vc exceeds collectable quantity V1 as the execution timing of the next supply operation.

Next, control device 20 determines whether required time TL for the mounting cycle scheduled to be executed in parallel with the next supply operation scheduled by S31 is shorter than required time Ts for the supply operation (S32). Here, as shown in FIG. 6, required time Tt for each PP cycle can be acquired in advance as the sum of required time TC for the collection cycle and required time TL for the mounting cycle. Specifically, required time Ttl for the first PP cycle (PP1) corresponds to the sum of required time TCI for the collection cycle and required time TL1 for the mounting cycle.

Required time TC for the collection cycle may vary according to the moving distance of mounting head 133, depending on factors such as the quantity of collection target components 92 and the installation position of feeder 122 being supplied. Further, required time TL of the mounting cycle may vary according to the moving distance of mounting head 133, depending on factors such as the quantity and the mounting positions of multiple components 92. Control device 20 analyzes control program M1 to calculate various required times required in later processing. Required time Ts of the supply operation may vary according to the pattern of the supply operation, but control device 20 may use a fixed value as required time Ts for the supply operation in the above determination (S32).

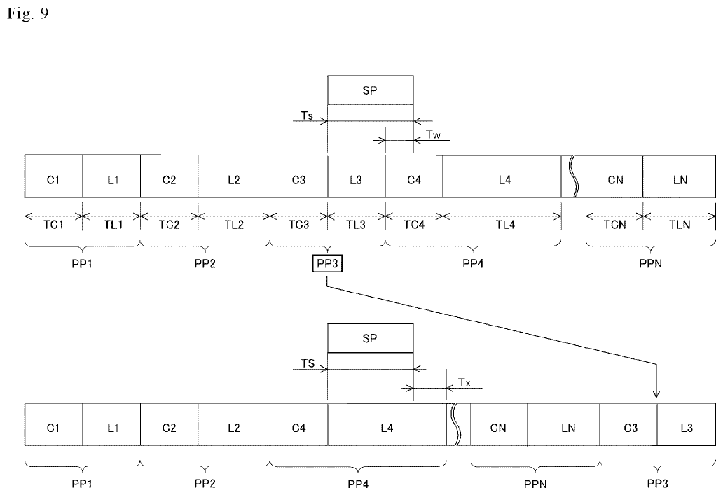

Here, as shown in the upper part of FIG. 9, when scheduled next supply operation SP is scheduled to be executed in parallel with the mounting cycle (L3) of the third PP cycle (PP3), respective required times Ts and TL3 are compared. For example, when required time Ts for supply operation SP is longer than required time TL3 for the mounting cycle (L3) (S32: Yes), when the collection operation for the component type (a) is included in the mounting cycle (C4) of the next fourth PP cycle (PP4), waiting time Tw for waiting for the completion of supply operation SP occurs.

Then, order adjustment section 25 executes the PP cycle adjustment process (S33). In the adjustment process, order adjustment section 25 adjusts the execution order of multiple PP cycles included in control program M1 under predetermined conditions, thereby preventing the occurrence of waiting time Tw as described above or shortening waiting time Tw. Order adjustment section 25 may adjust, for example, to execute the third PP cycle (PP3) in which waiting time Tw occurs as described above due to the scheduled execution before the second PP cycle (PP2) before the execution.

In the present embodiment, when the execution order of the PP cycle is adjusted, order adjustment section 25 adjusts the PP cycle to be later than the execution order set by control program M1. With this aspect, order adjustment section 25 can treat the PP cycle which is the adjustment target similarly to the recovery processing target, and can simplify various later processes. In addition, the “predetermined conditions” include conditions such as fixed or recommended execution sequences among multiple PP cycles.

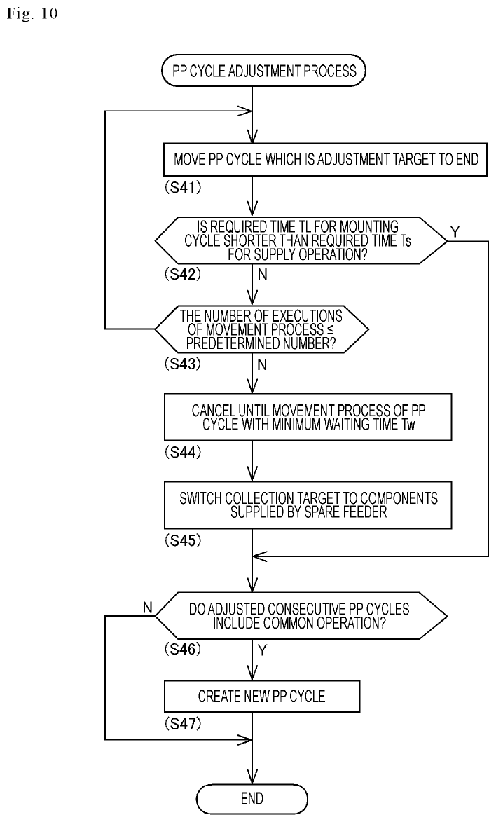

In the present embodiment, it is assumed that there is no predetermined condition as described above, and order adjustment section 25 moves the PP cycle which is the adjustment target to the end of all PP cycles as shown in FIG. 10 (S41). As a result, as shown in the lower part of FIG. 9, the third PP cycle (PP3) is rescheduled to be executed at the end, similarly to the recovery processing. Next, scheduled next supply operation SP is scheduled to be executed in parallel with the mounting cycle of the PP cycle that was scheduled to be executed immediately after the moved PP cycle. Control device 20 determines whether required time TL for the mounting cycle is shorter than required time Ts for the supply operation (S42).

For example, as shown in the lower part of FIG. 9, supply operation SP is scheduled to be executed in parallel with the mounting cycle (C4) of the fourth PP cycle (PP4). When required time Ts for the supply operation is shorter than required time TL4 for the mounting cycle (C4) (S42: Yes), surplus time Tx exists only for the difference, and waiting time Tw does not occur. When required time Ts for supply operation SP is longer than required time TL for the next candidate PP cycle (S42: No), and as long as the number of executions of the movement process to the end (S41) does not exceed a predetermined prescribed number (S43: Yes), the next candidate PP cycle is designated as the PP cycle which is the adjustment target, and the above processes (S41 and S42) are repeated.

The prescribed number described above is set to the maximum number of cycles from the next candidate PP cycle to the final PP cycle (PPN), and is appropriately set by the administrator or the like in consideration of the processing load or the like, or is set to a fixed value. When the number of executions of the movement process (S41) reaches the prescribed number (S43: No), order adjustment section 25, when the movement process (S41) is executed multiple times, cancels the movement process (S41) of the PP cycle with minimum waiting time Tw among multiple PP cycles that have become the adjustment target, and completes the adjustment with a part of multiple PP cycles returned to the original state (S44). Order adjustment section 25 may complete the adjustment in a state where the movement process (S41) is executed up to the predetermined number without canceling the movement process (S41).

When the number of executions of the movement process (S41) reaches the prescribed number (S43: No), when executing the collection operation of any PP cycle, waiting time Tw for waiting for the completion of supply operation SP occurs. In the present embodiment, in such a case, mounting control section 22 switches the collection target in the collection operation to components 92 supplied by spare feeder 61 (S45). As a result, mounting control section 22 executes multiple PP cycles whose execution order is adjusted, and when supply operation SP is executed at the scheduled execution timing, mounting control section 22 collects the same type of components 92 supplied by spare feeder 61 instead of transitioning to a standby state.

Thus, it is possible to transitioning to the mounting operation without generating waiting time Tw. However, in the collection cycle using spare feeder 61, since the movement of mounting head 133 to spare feeder 61 is accompanied, required time TL for the collection cycle may increase. Here, mounting control section 22 may compare waiting time Tw expected to occur with the extended time of required time TL due to using spare feeder 61, and may switch between waiting for waiting time Tw as it is or taking the components supplied by spare feeder 61 as a collection target. When spare feeder 61 is not provided or when the switching to spare feeder 61 is not permitted, the switching process (S45) described above may be omitted.

Spare feeder 61 described above may be a bulk feeder or a tape feeder as long as the same type of components 92 as bulk feeder 30 can be supplied. In the present embodiment, spare feeder 61 is assumed to be a tape feeder that feeds and moves a carrier tape accommodating components 92 to supply components 92. Although the total quantity of components 92 that can be supplied are reduced in the tape feeder compared to bulk feeder 30, the required time for the supply operation to supply individual components 92 is short, and components 92 can be supplied in a stable posture. Therefore, there is an advantage in that the recognition processing of the supply state can be omitted.

Subsequently, after the switching process (S45), or when required time TL for the next candidate mounting cycle is shorter than required time Ts for the supply operation due to the movement process (S41) (S42: Yes), after the final PP cycle (PPN), cycle generation section 26 determines whether the adjusted multiple PP cycles include a common operation (S46). The determination of the presence or absence of the common operation described is a determination as to whether the PP cycle in which the execution order is adjusted and other consecutive PP cycles include a collection operation and a mounting operation for the same type of components 92. The target of the determination of the presence or absence of the common operation (S46) may include the PP cycle which has already been moved to the end by the previous adjustment process, and the recovery processing target which is partially moved to the end with the execution of the mounting process.

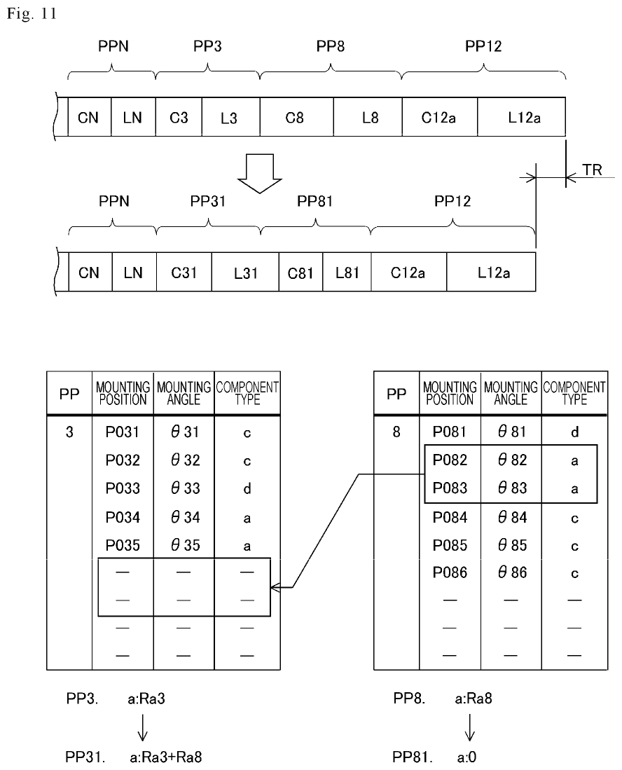

Specifically, it is assumed that the three PP cycles (PP3, PP8, and PP12) are moved to the end by multiple movement processes (S41), as shown in the upper part of FIG. 11. Here, in the third PP cycle (PP3) and the eighth PP cycle (PP8), as shown in the lower part of FIG. 11, it is determined that there is a common operation (S46: Yes) since the collection operation and the mounting operation of the component (a) supplied by bulk feeder 30 as a collection target are included. Cycle generation section 26 moves the set of the collection operation and the mounting operation described above, which are included in the eighth PP cycle (PP8), to the third PP cycle. Thus, cycle generation section 26 generates new PP cycles (PP31 and PP81) as shown in the upper part of FIG. 11 (S47).

Control device 20 obtains the required quantity (Ra3→Ra3+Ra8, Ra8→0) of each component (a) associated with the new PP cycles (PP31 and PP81). Cycle generation section 26 may further generate new PP cycles when a new PP cycle (PP81) and a consecutive PP cycle (PP12) include the common operation (collection operation and mounting operation for the same type of components 92). With this PP cycle generation process (S47), as shown in FIG. 11, the moving distance of mounting head 133 can be shortened in the new PP cycles (PP31 and PP81). As a result, the required time for the mounting process can be shortened by reduction time TR, thereby improving the efficiency of the mounting process.

When adjusted multiple PP cycles do not include the common operation (S46: No) or when the new PP cycles cannot be generated without satisfying predetermined conditions, the PP cycle generation process (S47) is not executed, and the adjustment process of the PP cycle (S33) is completed. The “predetermined conditions” described above include, for example, conditions such as fixed or recommended execution sequences among multiple mounting operations, or limitations on the quantity of collectable components 92 in one PP cycle based on the relationship with the number of suction nozzles 133.

After the PP cycle adjustment process as described above (S33) is completed, or when it is determined that waiting time Tw does not occur (S32: No), supply control section 24 executes the supply operation by bulk feeder 30 at the time when the calculated execution timing is reached (S34). After the supply operation by bulk feeder 30 is completed, state recognition section 23 executes recognition processing of the supply state of components 92 (S35). The supply operation (S34) and the recognition processing of the supply state (S35), which are described above, are the same as S21 and S22 executed in parallel with the loading process (S11) of board 91, and thus detailed description thereof will be omitted.

### 1-7. Effects of Configuration of First Embodiment

With the configuration of component mounting machine 10 and the component mounting method (FIG. 7), the execution order of multiple PP cycles is appropriately adjusted based on the required quantity and collectable quantity V1 (S33). Accordingly, it is possible to prevent occurrences such as insufficient collectable quantity V1 or waiting time Tw for waiting for the completion of the supply operation of bulk feeder 30, during the execution of the PP cycle. As a result, a decrease in production efficiency can be prevented.

### 2. Second Embodiment

Component mounting machine 10 and a component mounting method for executing a mounting process of components 92 using bulk feeder 30 will be described with reference to the drawings. The second embodiment is different from the first embodiment mainly in the configuration of the supply management process. Since other configurations are substantially the same, detailed descriptions thereof will be omitted.

### 2-1. Supply Management Process by Component Mounting Machine 10

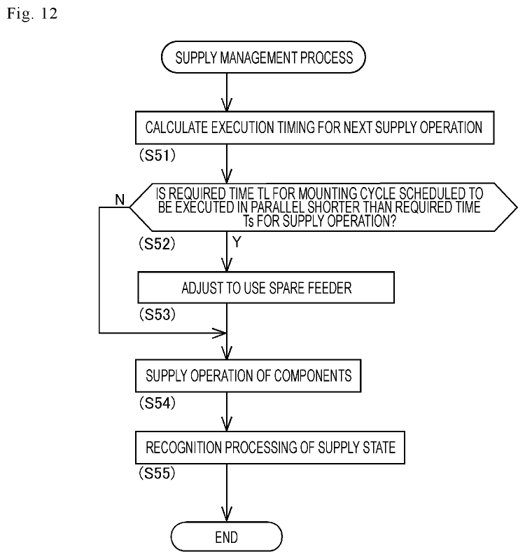

As shown in FIG. 12, each process (S51 to S52, S54 to S55) in the supply management process of the second embodiment is substantially the same as each process (S31 to S32, S34 to S35) in the supply management process of the first embodiment, and the PP cycle adjustment process (S33 in FIG. 8) is omitted. In the supply management process, when required time Ts for supply operation SP is longer than required time TL for the mounting cycle (S52: Yes), mounting control section 22 switches the collection target in the collection operation to components 92 supplied by spare feeder 61 (S53).

As a result, mounting control section 22 executes multiple PP cycles in the order set by control program M1, and when supply operation SP is executed at the scheduled execution timing, mounting control section 22 collects the same type of components 92 supplied by spare feeder 61 instead of transitioning to a standby state. Thus, it is possible to transitioning to the mounting operation without generating waiting time Tw. Further, since spare feeder 61 described above is a tape feeder, components 92 can be individually collected by feeding and moving the carrier tape, and the required time for the supply operation can be shortened. Further, since the tape feeder can supply components 92 in a stable posture, there is an advantage in that the recognition processing of the supply state can be omitted.

Here, mounting control section 22 switches to spare feeder 61 (S53) depending on the result of the determination as to whether waiting time Tw occurs (S52). On the other hand, mounting control section 22 may compare waiting time Tw expected to occur with the extended time of required time TL due to using spare feeder 61, and may switch between waiting for waiting time Tw as it is or taking the components supplied by spare feeder 61 as a collection target.

### 2-2. Effects of Configuration of Second Embodiment

Further, with the configuration of component mounting machine 10 and the component mounting method (FIG. 12), when the supply operation of bulk feeder 30 is required, since the collection target is switched to components 92 supplied by a spare tape feeder capable of supplying the same type of components as bulk feeder 30, the occurrence of waiting time for the completion of the supply operation of bulk feeder 30 can be prevented. As a result, a decrease in production efficiency can be prevented.

### 3. Modifications of First and Second Embodiments

In the first and second embodiments, bulk feeder 30 supplies components 92 to be mounted on board 91 by component mounting machine 10. In the first and second embodiments, a rectangular chip component is exemplified as component 92 described above when viewed from the thickness direction. On the other hand, component 92 is used in a board work machine that executes a predetermined work on board 91, such as component mounting machine 10, and various articles can be applied as long as the articles can be supplied in a state accommodated in cavity 51 in bulk feeder 30. For example, bulk feeder 30 may supply a solder ball formed in a spherical shape.

### REFERENCE SIGNS LIST

10: component mounting machine, 11: board conveyance device, 12: component supply device, 122: feeder, 13: component transfer device, 20: control device, 21: storage section, 22: mounting control section, 23: state recognition section, 24: supply control section, 25: order adjustment section, 26: cycle generation section, 30: bulk feeder, 61: spare feeder (tape feeder), 91: board, 92: component, M1: control program

1. A component mounting machine comprising:
a mounting control section configured to execute a mounting process based on a control program in which an execution order of a PP cycle including a collection operation of components and a mounting operation of mounting the components on a board is set;
a supply control section configured to, when the collectable quantity of components in a bulk feeder configured to supply multiple components in a bulk state is less than a reference value, cause the bulk feeder to execute a supply operation of the components in parallel to a mounting cycle in which the mounting operation is repeated multiple times; and
an order adjustment section configured to, when a required time for the mounting cycle scheduled to be executed in parallel with the next supply operation scheduled based on the current collectable quantity is shorter than a required time for the supply operation, adjust an execution order of the PP cycle including the mounting cycle.

2. The component mounting machine according to claim 1, wherein the order adjustment section is configured to, when adjusting the execution order of the PP cycle, adjust the PP cycle to be later than the execution order set by the control program.

3. The component mounting machine according to claim 1, further comprising:
a cycle generation section configured to, when the PP cycle in which the execution order is adjusted and other consecutive PP cycles include the collection operation and the mounting operation for the same type of components, generate a new PP cycle including the collection operation and the mounting operation for at least the same type of components among multiple consecutive PP cycles.

4. The component mounting machine according to claim 1, wherein the reference value is set to 1.

5. The component mounting machine according to claim 1,
wherein a spare feeder configured to supply the same type of components as the bulk feeder is provided, and
the mounting control section is configured to, when executing the collection operation, switch a collection target to the components supplied by the spare feeder when waiting time for waiting for completion of the supply operation of the components by the bulk feeder occurs.

6. The component mounting machine according to claim 5, wherein the spare feeder is a tape feeder configured to feed and move a carrier tape accommodating the components to supply the components.

7. A component mounting machine comprising:
a component supply device including a bulk feeder configured to supply multiple components in a bulk state, and a tape feeder configured to feed and move a carrier tape accommodating the same type of components as the bulk feeder to supply the components;
a mounting control section configured to execute a mounting process based on a control program in which an execution order of a PP cycle including a collection operation of the components and a mounting operation of mounting the components on a board is set; and
a supply control section configured to, when the collectable quantity of components in the bulk feeder is less than a reference value, cause the bulk feeder to execute a supply operation of the components in parallel with the PP cycle,
wherein the mounting control section is configured to, when executing the collection operation, switch a collection target to the components supplied by the tape feeder when waiting time for waiting for completion of the supply operation of the components by the bulk feeder occurs.

8. A component mounting method comprising:
a mounting control step of executing a mounting process based on a control program in which an execution order of a PP cycle including a collection operation of components and a mounting operation of mounting the components on a board is set;
a supply control step of causing, when the collectable quantity of components in a bulk feeder configured to supply multiple components in a bulk state is less than a reference value, the bulk feeder to execute a supply operation of the components in parallel to a mounting cycle in which the mounting operation is repeated multiple times; and
an order adjustment step of adjusting, when a required time for the mounting cycle scheduled to be executed in parallel with the next supply operation scheduled based on the current collectable quantity is shorter than a required time for the supply operation, an execution order of the PP cycle including the mounting cycle.
